(19) United States
(12) Patent Application Publication
(10) Pub. No.: US 2010/0264294 A1
(43) Pub. Date: Oct. 21, 2010

(54) MULTI-FOCAL SPOT GENERATOR AND MULTI-FOCAL MULTI-SPOT SCANNING MICROSCOPE

(75) Inventors: Sjoerd Stallinga, Eindhoven (NL); Levinus P. Bakker, Shanghai (CN); Dirk L.J. Vossen, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/742,985

(22) PCT Filed: Nov. 19, 2008
(86) PCT No.: PCT/IB2008/054860

§ 371 Date: May 14, 2010

(30) Foreign Application Priority Data
Nov. 23, 2007 (EP) 07301570.3

(51) Int. Cl. G02B 27/64; G02B 26/08; H01L 27/14

(52) U.S. Cl. 250/201.3; 359/237; 250/208.1

(57) ABSTRACT

The invention relates to a spot-generator (10) having: an entrance surface (12) for receiving an incident light beam (20) and an exit surface (14) for transmitting the light beam, the entrance surface defining an entrance side (16) and the exit surface defining an exit side (18), wherein the spot generator is designed to modulate the incident light beam to generate on the exit side a plurality of separate light spots. According to the invention, the plurality of light spots comprises a first light spot (22) generated in a first focal plane (24) and a second light spot (26) generated in a second focal plane (28), the first focal plane and the second focal plane being essentially perpendicular to the mean propagation direction of the exit light beam, and wherein the first light spot (22) differs from every other light spot generated on the exit side by the spot generator in the projection of its position on a plane essentially perpendicular to the mean propagation direction of the exit light beam. Advantageously, the light spots of the plurality of separate light spots have identical spectra. The invention further relates to a multi-spot scanning microscope and to a method of generating an image of a microscopic sample. Advantageously, the method comprises the step of generating a three-dimensional image of the sample.

### FIELD OF THE INVENTION

The present invention relates to a spot generator having an entrance surface for receiving an incident light beam and an exit surface for transmitting the light beam, the entrance surface defining an entrance side and the exit surface defining an exit side, wherein the spot generator is designed to modulate the incident light beam to generate on the exit side a plurality of separate light spots.

The invention also relates to a multi-spot scanning microscope comprising a spot generator of the type specified above, a sample assembly for holding a sample to be illuminated via the spot generator, imaging optics arranged to collect light from the first and from the second focal planes of the spot generator, and a pixelated photodetector arranged to detect light collected by the imaging optics.

The invention further relates to a method of generating an image of a microscopic sample.

### BACKGROUND OF THE INVENTION

Optical scanning microscopy is a well-established technique for providing high resolution images of microscopic samples. According to this technique, a distinct, high-intensity light spot is generated in the sample. Since the sample modulates the light of the light spot, detecting and analyzing the light coming from the light spot yields information about the sample at that light spot. A full two-dimensional or three-dimensional image of the sample is obtained by scanning the relative position of the sample with respect to the light spots.

Throughout this application, a light spot is defined as a spatial region where the intensity (i.e. the time-averaged energy-flux of the light field, of units W/m²), averaged over the region, is at least two times larger than in a surrounding region having a volume at least an order of magnitude larger than the volume of the light spot itself. Preferably, each light spot generated in the sample is diffraction-limited. Preferably, the intensity in the light spot is at least an order of magnitude higher than in the surrounding region.

A plurality of light spots is typically generated from a collimated beam of light that is suitably modulated by a spot generator so as to form the light spots at a certain distance from the spot generator. According to the state of the art, the spot generator is either of the refractive or of the diffractive type. Refractive spot generators include lens systems, such as micro-lens arrays, and phase structures, such as the binary phase structure proposed in WO2006/035393. These systems are well-understood. Therefore a spot generator may be characterized either by its physical structure, or, equivalently, by the light spots it generates from an incident monochromatic plane wave. In particular, a binary phase structure as proposed in WO2006/035393 is most easily characterized by the light pattern which it generates. The physical structure of the binary phase structure is generally rather complicated, but in fact it can be computed from the specific pattern it generates, as outlined in WO 2006/035393.

A light-spot generated in the sample may be imaged from any direction, by collecting light that leaves the light spot in that direction. In particular, the light spot may be imaged in transmission, that is, by detecting light on the far side of the sample, the far side being the side behind the sample, seen in the mean propagation direction of the light generating the light spot. Alternatively, a light spot may be imaged in reflection, that is, by detecting light on the near side of the sample, the near side being the side in front of the sample, seen in the mean propagation direction of the light generating the light spot. In the technique of confocal scanning microscopy, the light spot is customarily imaged in reflection via the optics generating the light spot, i.e. via the spot generator.

U.S. Pat. No. 6,248,988 proposes a multi-spot scanning optical microscope featuring an array of multiple separate focused light spots illuminating the object and a corresponding array detector detecting light from the object for each separate spot. Scanning the relative positions of the array and object at slight angles to the rows of the spots then allows an entire field of the object to be successively illuminated and imaged in a swath of pixels. Thereby the scanning speed is considerably augmented.

In the state of the art, three-dimensional images of the sample are generated from a set of two-dimensional images, where each image is taken individually at a predetermined depth in the sample. More precisely, each of the two-dimensional images is obtained by scanning the sample in a single focal plane, the focal plane being defined perpendicular to the principal propagation direction of the light generating the light spots in the sample. Note that the light generating the light spots only has a mean propagation direction, since it is composed of plane waves travelling in (at least slightly) different directions. When the sample has been scanned and an image has been thus obtained at a first focal plane, a second focal plane parallel to the first focal plane is selected by changing the distance between the spot generator and the sample (i.e. the depth), and the scanning process is repeated. To change the spot position in depth, the method usually used consists in moving the spot generator (an objective lens for example) with respect to the sample along the depth direction, i.e. perpendicular to the focal plane. Inversely, it is also known to move the sample holder with respect to the spot generator.

A problem is that in order to generate three-dimensional images, the mutual positions of the spot generator and the sample must be accurately adjusted each time the sample is to be scanned along a new focal plane. A further problem is the time needed for scanning successively across different focal planes when the sample is not fixed, as in the case of living micro-organisms.

A similar problem arises in the context of phase imaging. Generally, a sample modifies both the amplitude (by absorption and scattering) and the phase (by optical path=refractive index×thickness) of the incident light. Variations in the modulations of amplitude and phase from point to point generate the contrast in microscopic images of the sample. Conventional transmission microscopy is only sensitive to amplitude modulations. However, phase imaging techniques are often advantageous, because phase modulations provide highly relevant information on e.g. biological samples. Such techniques exist, for example the phase contrast technique of Zernike. It has been known for quite some time that out-of-focus light provides phase information (C. J. R. Sheppard, Defocused transfer function for a partially coherent microscope and application to phase retrieval, Journal of the Optical Society of America A, Vol. 21, pp. 828-831, 2004). A recent attempt to use this insight is the so-called quantitative phase imaging technique, which is commercialized by IATIA (http://www.iatia.com.au). According to this technique (see WO 00/26622), (transmission) microscope images I1 and I2 of two nearby focal planes, typically spaced a few μm apart, are taken and processed to make a phase map relating to the plane situated halfway between the two imaged planes. The processing part entails the steps of (1) taking the intensity difference I2−I1, (2) normalizing with the sum to factor out the amplitude modulation, giving (I2−I1)/(I2+I1), and (3) applying an electronic filter in order to equalize the response over the spatial frequencies up to the cut-off, the filter having the character of the so-called inverse Laplacian at low spatial frequencies in order to boost the response in this frequency region. The processing steps (2) and (3) may not be needed in case a qualitative visualization of phase information is desired, but are needed in case quantitative information on the phase and (by implication refractive index) is desired. Clearly, it would be desirable to acquire the images I1 and I2 simultaneously, rather than successively.

Another problem of the prior art that is addressed by the invention is that the focus position of a thin sample needs to be continuously adjusted by mechanical means. Electronic focussing, i.e. interpolating between the set of images at different focal planes in order to obtain the best-focus image of the sample, is desirable.

It is therefore an object of the invention to provide improved means for optically probing a microscopic sample at different focal planes. In particular the invention aims at providing simpler and cheaper 3D imaging microscopes.

This object is achieved by the features of the independent claims. Further specifications and preferred embodiments are described in the dependent claims.

### SUMMARY OF THE INVENTION

The invention provides a spot generator having an entrance surface for receiving an incident light beam, and an exit surface for transmitting the light beam, the entrance surface defining an entrance side and the exit surface defining an exit side, wherein the spot generator is designed to modulate the incident light beam to generate on the exit side a plurality of separate light spots. According to the invention, the plurality of light spots comprises a first light spot generated in a first focal plane and a second light spot generated in a second focal plane, the first focal plane and the second focal plane being essentially perpendicular to the mean propagation direction of the exit light beam, and wherein the first light spot differs from every other light spot generated on the exit side by the spot generator in the projection of its position on a plane essentially perpendicular to the mean propagation direction of the exit light beam. It is convenient to refer to the mean propagation direction of the exit light beam as the z-direction. A plane perpendicular to the mean propagation direction of the exit light beam then defines the x-y-directions. Among all the light spots generated by the spot generator, the first light spot is thus unique in its x-y-position. Therefore, when the plurality of light spots is imaged, the first light spot can be easily and unequivocally identified by its x-y-position, which is highly advantageous for analyzing the output of the photodetector. The incident light beam is preferably a monochromatic plane wave. Preferably, the wave is deformed by the spot generator such that the mean propagation direction of the exit wave coincides with the propagation direction of the incident plane wave. However, if the spot generator is sufficiently asymmetric with respect to the incident light beam, the mean propagation direction of the exit light beam will differ from the propagation direction of the incident light beam. The first focal plane and the second focal plane are understood to be separated by a distance such that the first light spot's luminosity in the second focal plane measures at most a third of its luminosity in the first focal plane, and the second light spot's luminosity in the first focal plane measures at most a third of its luminosity in the second focal plane. For some applications, in particular phase imaging, generating more than two focal planes may not be required. However, for three-dimensional imaging it can be convenient to generate many separate light spots distributed over many different focal planes, wherein each light spot is unique in its x-y-coordinates.

Preferably, the entrance surface and the exit surface are situated on opposite sides of the spot generator. According to this aspect of the invention, the spot generator is designed to work in a transmissive manner, that is, it does not alter significantly the total momentum of the incident light. For this purpose, the spot generator is preferably at least partly transparent.

Alternatively, the entrance surface and the exit surface are the same. This design applies to a spot generator designed to generate the light spots in a reflective mode, that is, the total momentum of the incident light is essentially reversed. For this purpose, the spot generator is preferably at least partly non-transparent. Accordingly, the incident light beam hits the spot generator, e.g. a non-transparent phase structure, on the entry surface, is modulated by reflection and leaves the spot generator from the same entry surface. Hence the entry surface also acts as exit surface.

Preferably, the plurality of separate light spots comprises a first plurality of separate light spots situated in the first focal plane and a second plurality of separate light spots situated in the second focal plane. Providing more than one spot is advantageous for simultaneously gathering information about a larger volume within a sample. Preferably the spots of the first plurality and of the second plurality respectively form a first lattice and a second regular lattice. The lattices may in particular be rectangular lattices.

In a first embodiment, the spot generator comprises a first section for generating the first plurality of light spots and a second section for generating the second plurality of light spots. According to this embodiment, a first part of the incident light is modified by the first section, and a second part is modified by the second section, wherein the first part is focussed onto the first focal plane and the second part is focussed onto the second focal plane.

Alternatively, in a second embodiment, the spot generator comprises a plurality of identical unit cells for generating both the first plurality of light spots and the second plurality of light spots. Each unit cell may, for example, comprise a first micro-lens and a second micro-lens, wherein the first micro-lens generates the first light spot and the second micro-lens generates the second light spot. Preferably, the first plurality of light spots and the second plurality of light spots are evenly and equally distributed over a common region in the x-y-plane, in other words, they are interlaced, where by definition two pluralities of points are interlaced if the combined plurality of points may be decomposed into an array of at least two identical unit cells.

Preferably, every light spot generated on the exit side by the spot generator differs from every other light spot generated on the exit side by the spot generator in the projection of its position on a plane essentially perpendicular to the mean propagation direction of the exit light beam. In other words, every light spot generated on the exit side by the spot generator is unique in its projection of its position on the x-y-plane. When detecting the light spots, each light spot may thus be easily identified simply by its x-y-coordinates.

Preferably, the light spots of the plurality of separate light spots have identical spectra. The design of a spot generator for monochromatic spots is simpler due to the absence of chromatic aberration.

Preferably, the spot generator comprises a periodic binary phase structure. More preferably, the spot generator is a binary phase structure of the type proposed in WO 2006/035393. That structure consists of a periodic set of unit cells of size pₓ×p_{y}, where pₓ is the pitch in an x-direction and p_{y} is the pitch in a y-direction. Each unit cell has a binary height profile, that is, there are only two possible values for the height of the unit cell at an arbitrary point of the cell, which simplifies manufacturing. The binary phase structure diffracts the incident beam into a large number of orders. These orders are collimated beamlets, each beamlet travelling in a certain direction. At the focal planes, all these orders add up coherently to produce an array of light spots. The amplitude and relative phase of these orders must be chosen correctly to make the desired type of light spot. The design of such a structure mainly consists in finding a pattern for the unit cell that generates the correct amplitudes and phases of the diffraction orders. Preferably, the phase structure is transparent, but the first plurality and the second plurality of light spots could also be generated by a non-transparent, reflective phase structure, wherein the light spots are generated from light reflected from the phase structure. Alternatively, the spot generator may comprise a micro-lens array, wherein each lens of the array is designed to generate a single light spot.

The invention also provides a multi-spot scanning microscope comprising a spot generator of the type discussed above, a sample assembly for holding a sample to be illuminated via the spot generator, imaging optics arranged to collect light from the first and from the second focal planes of the spot generator, and a pixelated photodetector arranged to detect light collected by the imaging optics. Since the spot generator provides different focal planes, the need for scanning the sample along the z-direction is reduced or even eliminated. In consequence, the microscope of the invention produces an array of spots which, when detected simultaneously, can be used for generating a 3D image. The multi-focal multi-spot scanning microscope of the invention can advantageously be used for phase imaging, and in particular for the quantitative phase imaging technique mentioned above. Preferably, the depth of field of the imaging optics is sufficiently large for imaging simultaneously a first light spot situated in the first focal plane and a second light spot situated in the second focal plane, with the resolution of the order of the size of the pixels of the pixelated photodetector or higher. This can be achieved by choosing an imaging system having a relatively small numerical aperture, although a small NA also entails a smaller resolution (diffraction limit=wavelength divided by sum of illumination and imaging NA). So, there is a trade-off between high resolution and large depth of field. More preferably, the imaging optics is designed for imaging simultaneously all light spots generated by the spot generator in a multitude of focal planes. Thereby the need of adjusting the imaging optics to different focal planes is avoided. The proposed multi-focal multi-spot scanning microscope thus allows for simultaneous rather than sequential acquisition of images from different focal planes, which has the advantage of inherently good alignment between the focal planes. In a preferred embodiment, the imaging optics is situated behind the sample assembly, for collecting light transmitted toward the spot generator and the sample placed in the sample assembly. Such an arrangement is suited for transmission microscopy. The multi-focal multi-spot scanning microscope of the invention can also advantageously be used for full electronic focussing by interpolating between the images taken at respective depths in order to find the best-focus image of the sample.

The invention further provides a method of generating an image of a microscopic sample, comprising the steps of:

placing a spot generator in front of the sample;

directing a light beam onto the spot generator to generate a plurality of separate light spots in the sample, the plurality of light spots comprising a first light spot centred in a first focal plane and a second light spot centred in a second focal plane, the first focal plane and the second focal plane being essentially perpendicular to the mean direction of the light beam leaving the spot generator, wherein the first light spot differs from every other light spot generated within the sample by the spot generator in the projection of its position on a plane essentially perpendicular to the mean propagation direction of the light beam leaving the spot generator.

on the far side of the sample, detecting light from the first light spot while simultaneously detecting light from the second light spot.

Preferably the light is detected on the far side of the sample. Preferably it is detected using a pixelated photodetector, and the photodetector's output is processed using integrated circuitry connected to a computer, preferably a PC.

According to the invention the method may further comprise the additional step of:

generating a three-dimensional image of the sample.

Since the sample is generated using data measured simultaneously at different focal planes, an improved quality as compared to the state of the art may be expected due to the absence of alignment errors.

The method may further comprise the additional step of:

generating a phase contrast image of the sample.

The method may further comprise the additional step of:

electronic focussing.

### BRIEF DESCRIPTION OF THE DRAWINGS

Other aspects, purposes and advantages of the invention will become clearer upon reading the following detailed description of a preferred embodiment of the latter, given by way of non restrictive example and made in reference to the annexed drawings, in which:

FIG. 1 is a schematic view of a multi-spot scanning microscope;

FIG. 2 schematically shows a planar array of light spots of a prior-art spot generator of a multi-spot scanning microscope;

FIG. 3 is a schematic representation of an array of light spots comprising two interlaced arrays situated in different focal planes;

FIG. 4 is a schematic representation of an array of light spots comprising two adjacent arrays situated in different focal planes;

FIG. 5 is a schematic side view of the interlaced arrays of FIG. 3;

FIG. 6 is a schematic side view of the adjacent arrays of FIG. 4;

FIG. 7 is a schematic bottom view of the spot generator used to generate the light spots of FIG. 3;

FIG. 8 is a schematic bottom view of the spot generator used to generate the light spots of FIG. 4;

FIG. 9 is a schematic side view of a spot generator generating four interlaced arrays of light spots;

FIG. 10 is a schematic side view of a spot generator generating four adjacent arrays of light spots;

FIG. 11 is a schematic bottom view onto a unit cell of a binary phase structure for generating light spots in different focal planes.

### DESCRIPTION OF PREFERRED EMBODIMENTS

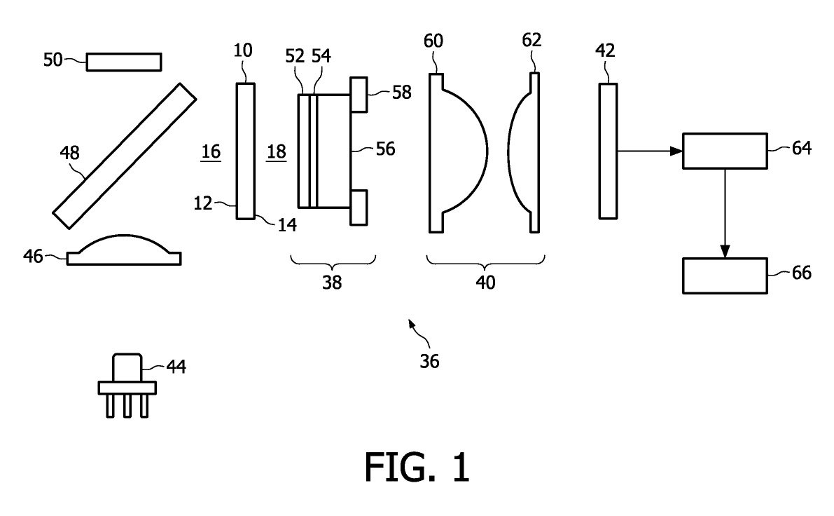

FIG. 1 schematically shows a multi-spot scanning microscope, comprising a laser 44, a collimator lens 46, a beam splitter 48, a forward-sense photodetector 50, a spot generator 10, a sample assembly 38, imaging optics 40, a pixelated photodetector 42, a video processing integrated circuit (IC) 64, and a personal computer (PC) 66. The sample assembly 38 comprises a cover slip 52, a sample layer 54, a microscope slide 56, and scan stage 58. The assembly consisting of the cover slip 52, the sample layer 54, and the microscope slide is placed on the scan stage 58. The imaging optics 40 comprises a first lens 60 and a second lens 62. The laser 44 emits a light beam (not shown) that is collimated by the collimator lens 46 and split by the beam splitter 48. The transmitted part of the light beam is captured by the forward-sense photodetector 50 for measuring the light output. The measured data regarding the light output is used by a laser driver (not shown), to control the light output by the laser. The reflected part of the light beam is incident on the spot generator 10. The spot generator 10 has an entrance side 12 and an exit surface 14. The entrance surface 12 defines an entrance side 16, while the exit surface 14 defines and exit side 18. In accordance with the invention, the spot generator 10 defines a set of distinct focal planes (not shown) on the exit side 18, each focal plane being perpendicular to mean propagation direction of the light on the exit side 18. The spot generator 10 is a periodic binary phase structure of the type described in WO 2006/035393 and designed specifically for the wavelength of the laser source 44 and for perpendicular incidence of the laser light reflected by the beam splitter 48. Alternatively, the spot generator 10 could be an array of micro-lenses. On the entrance side 16, in front of the spot generator 10, the incident laser light is well-approximated by a plane wave, with wavefronts extending parallel to the spot generator 10. The spot generator 10 modulates the incident light beam to generate in each of the focal planes on the exit side 18 an array of separate light spots. The distance between the spot generator 10 and the sample layer 54 is chosen such that all or at least some of the light spots generated on the exit side 18 come to lie within the sample layer 54. The sample layer 54 can be displaced relative to the light spots via an electric motor (not shown) coupled to the scan stage 56. Light from the light spots generated in the sample layer 54 by the spot generator 10 is collected by the imaging optics 40 and transmitted to the pixelated photodetector 42. In accordance with the invention, the light spots generated by the spot generator 10 have unique x-y-positions, that is, every spot generated on the exit side 18 differs from every other spot generated on the exit side 18 in its position's projection onto one of the focal planes. This has the advantage that every light spot is unequivocally identifiable by its x-y-position. The images captured by the pixelated photodetector 42 are processed by the video processing IC 64 to an image that is displayed and possibly analyzed or further treated by the PC 66.

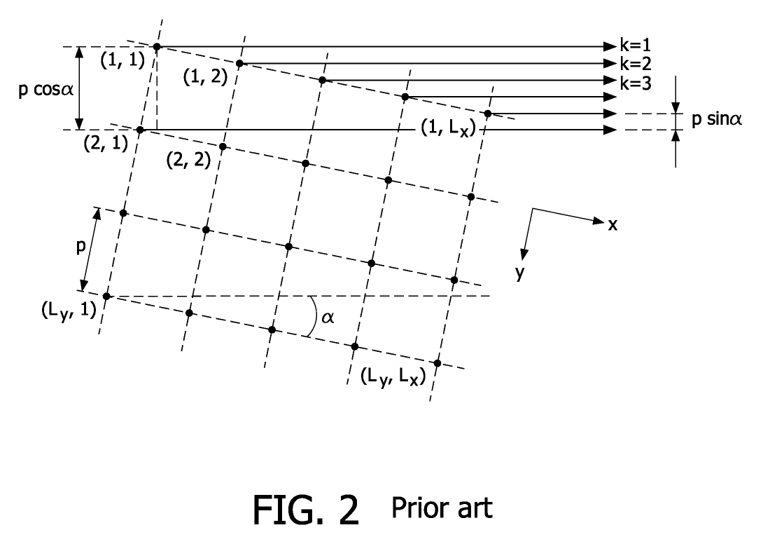

Turning now to FIG. 2, there is shown an array of light spots generated by a prior-art spot generator. The array defines an x-y-plane, which is perpendicular to the propagation direction of the light from which the light spots are generated. The light spots composing the array all lie in the x-y-plane. The array forms a quadratic lattice, with a lattice pitch p. The light spots are labelled (I, J), where I and J respectively refer to the x and y coordinates. The light spots are scanned with respect to the sample in a scanning direction having an angle α with respect to the x-axis defined by the array of light spots. Thus each light spot scans the sample along a distinct straight line (K=1, 2, 3) with the distance between two adjacent trajectories (e.g., K=1 and K=2) being significantly shorter than the lattice pitch P.

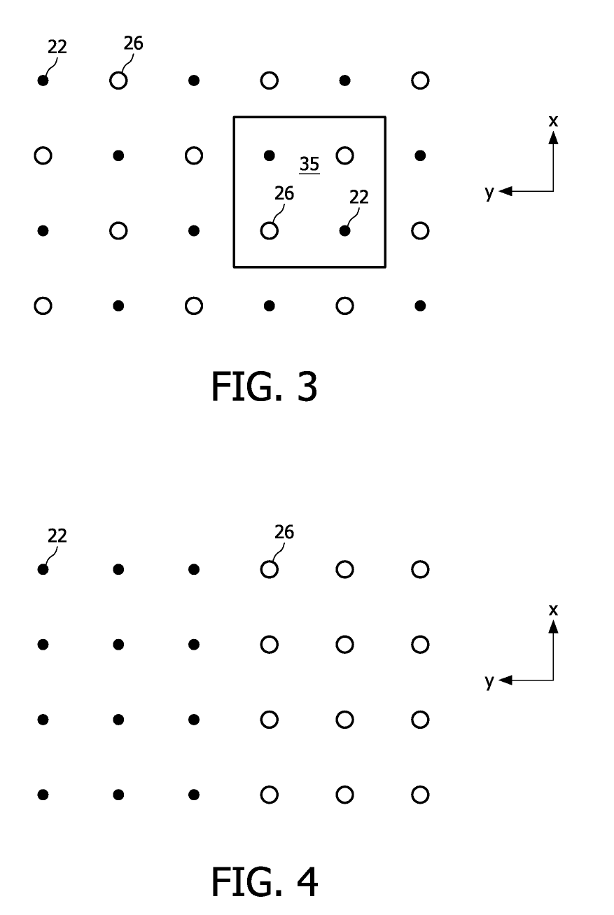

Turning now to FIG. 3, there is shown an array of light spots generated by a spot generator according to the invention. The array comprises a first sub-array of light spots 22 (full dots) situated in a first focal plane and a second sub-array of light spots 26 (empty dots) situated in a different, second focal plane. Shown is the projection of the array on the x-y-plane, the x-y-plane being defined perpendicular to the mean propagation direction of the light generating the light spots 22, 26. The light spots 22, situated in the first focal plane, thus have Cartesian coordinates (x, y, z₁) while the light spots 26, situated in the second focal plane, have Cartesian coordinates (x, y, z₂), where z₁ and z₂ differ. The light spots 22, 26 have essentially the same spectrum and differ only in their three-dimensional positions. The first array of light spots 22 (full dots) and the second array of light spots 26 (empty dots) are interlaced in the sense that the combined array 22, 26 (full and empty dots) may be decomposed into a set of identical unit cells 35. Every unit cell 35 (only one is shown, the others being identical) comprises two light spots 22 situated in the first focal plane and two light spots 26 situated in the second focal plane. The spot generator (not shown) is analogously composed of identical unit cells, with a one-to-one correspondence between unit cells of the spot generator and unit cells 35 of the array of light spots (22, 26).

Turning now to FIG. 4, there is shown an array of light spots generated by another embodiment of the spot generator according to the invention (not shown). The array of light spots is composed of a first array of light spots 22 (full dots) and a second array of light spots 26 (empty dots). Both the first array and the second array lie parallel to the x-y-plane with the z-axis being defined as the mean propagation direction of the light leaving the spot generator to generate the light spots 22, 26. Both the first array (full dots) and the second array (empty dots) form a quadratic lattice. Note that the first array (full dots) and the second array (empty dots) are not interlaced but adjacent.

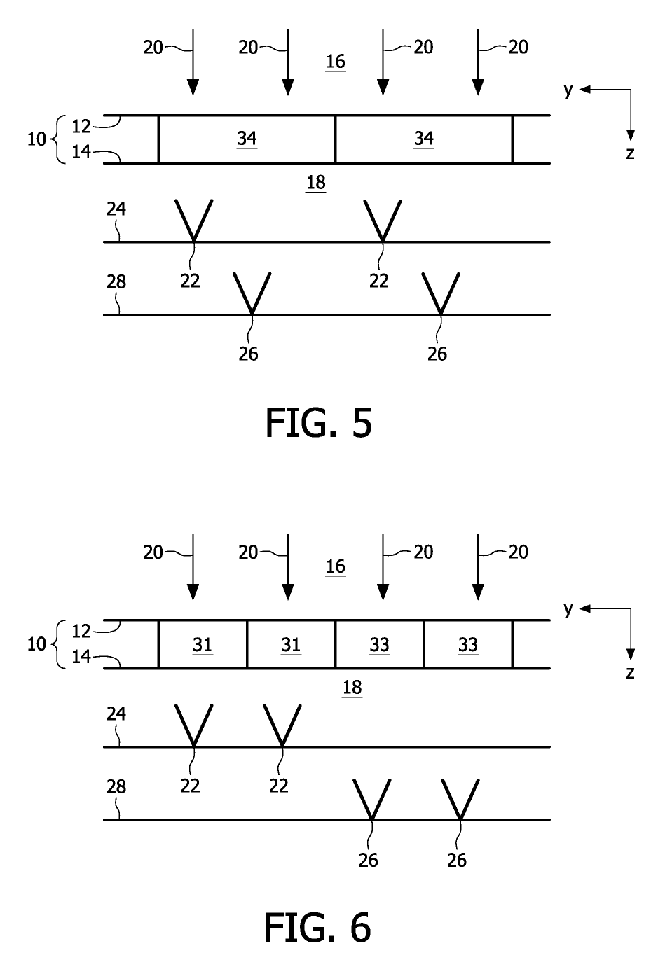

Turning now to FIG. 5, there is shown a schematic side view of a spot generator 10 modulating incident light 20 to generate the arrays of light spots 22, 26 discussed with reference to FIG. 3. The light 20 on the exit side 16 is essentially a monochromatic plane wave. The z-direction is defined as the mean propagation direction of the light 20 on the exit side 18. The light spots 22 of the first plurality of light spots lie in a first focal plane 24, while the light spots 26 of the second plurality of light spots lie in a second focal plane 28. The spot generator 10 is a periodic binary phase structure composed of identical unit cells 34. Note the one-to-one correspondence between each unit cell 34 of the spot generator 10 and each unit cell 35 of the array of light spots (see FIG. 3). In a simplified picture, each unit cell 34 of the spot generator 10 generates exactly one unit cell 35 of the array of light spots shown in FIG. 3. In reality, however, all unit cells 34 of the spot generator 10 contribute to generating a particular unit cell 35 of the array of light spots. Although only two unit cells 34 are fully shown in the Figure, the spot generator in reality comprises many more unit cells, generating a large number of first light spots 22 and of second light spots 26.

Turning now to FIG. 6, there is shown a spot generator 10 modulating an incident light beam 20 to generate the adjacent arrays of light spots 22, 26 discussed above with reference to FIG. 4. The first plurality of light spots 22 is situated in a first focal plane 24, and the second plurality of light spots 26 is situated in a second focal plane 28. The spot generator 10 comprises a first section composed of unit cells 31 of a first type and a second section composed of unit cells 33 of a second type. There is a one-to-one correspondence between each unit cell 31 of the first type and each light spot 22 generated in the first focal plane 24. Furthermore, there is a one-to-one correspondence between each unit cell 33 of the second type and each light spot 26 generated in the second focal plane 28. It should be noted that in each focal plane, the light intensity is negligible except for those parts where the focal planes cut one of the light spots 22, 26 (the same applies to the light spots discussed above with reference to FIG. 5). Furthermore, in the first focal plane 24, the intensities of the light spots 26 centred in the second focal plane 28 are negligible. Similarly, in the second focal plane 28, the intensities of the light spots 22 situated in the first focal plane 24 are negligible.

Turning now to FIG. 7, there is illustrated the spot generator 10 discussed above with reference to FIGS. 3 and 5, now seen against the z-direction. The spot generator 10 is composed of adjacent identical unit cells 34. Although there is shown a total of six unit cells 34, in practice the spot generator 10 comprises many more unit cells 34. As stated before, although there is a one-to-one correspondence between each unit cell 34 of the spot generator 10 and each unit cell 35 of the array of generated light spots (see FIGS. 3 and 5), each light spot 22, 26 (not shown) results, in fact, from light coming from different unit cells 34 of the spot generator 10. The array of light spots generated by the spot generator 10 is of quadratic symmetry. However, any other two-dimensional periodic symmetry is possible without departing from the scope of the invention.

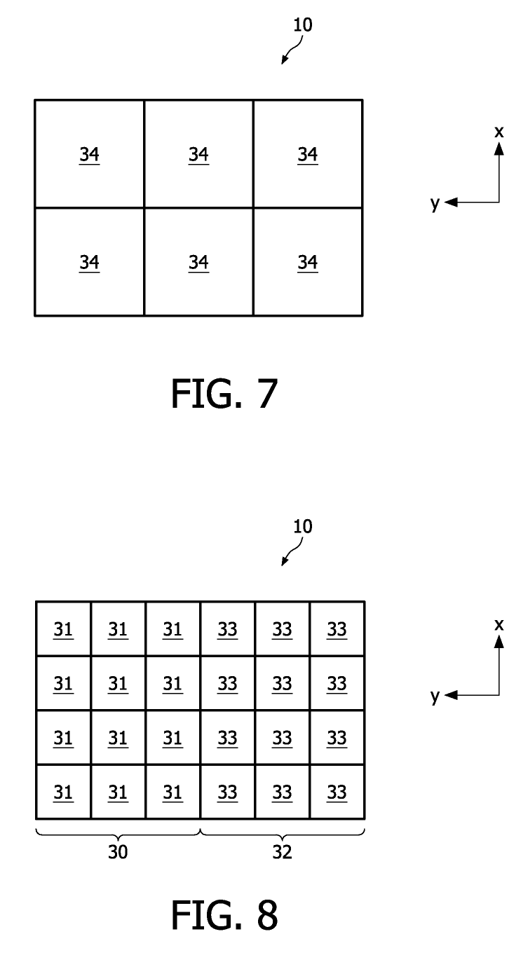

Turning now to FIG. 8, there is illustrated the spot generator 10 discussed above with reference to FIGS. 4 and 6, now seen against the z-direction. The spot generator 10 comprises a first periodic binary phase structure 30 and a second periodic binary phase structure 32, the two binary phase structures 30, 32 being adjacent. The first binary phase structure 30 is composed of identical unit cells 31, while the second binary phase structure 32 is composed of elementary unit cells 33. The first binary phase structure 30 generates the first plurality of light spots 22 situated in the first focal plane 24, while the second binary phase structure 32 generates the second plurality of light spots 26 situated in the second focal plane 28 (see FIGS. 4 and 6).

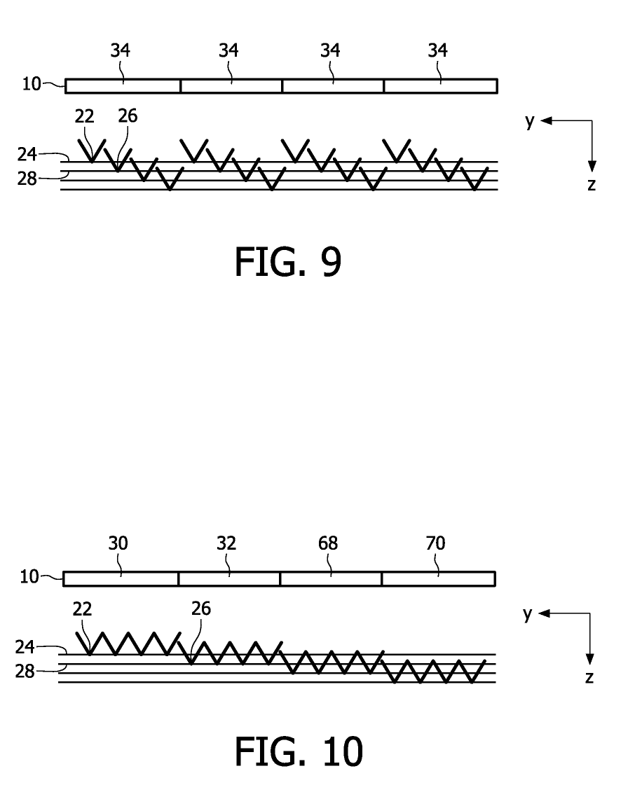

Turning now to FIG. 9, there is shown a schematic side view of a spot generator 10 which is similar in spirit to the embodiment described above with reference to FIGS. 5 and 7. The spot generator 10 generates four arrays of light spots, each array being situated in a separate focal plane parallel to the x-y-plane, where the x-y-plane is perpendicular to the mean direction of the modulated light. The spot generator is composed of identical unit cells 34. Each unit cell may either be a unit cell of a periodic binary phase structure or a unit cell comprising four different lenses having different focal lengths, each lens generating exactly one light spot.

Referring now to FIG. 10, there is shown another embodiment of a spot generator 10, similar in spirit to the embodiment explained with reference to FIGS. 4, 6 and 8. The spot generator 10 generates four arrays of light spots, situated in four separate focal planes parallel to the x-y-plane, where the z-direction coincides with the mean propagation direction of the modulated light. The spot generator 10 is composed of adjacent, different sections 30, 32, 68 and 70, which respectively generate the four arrays of light spots shown in the Figure.

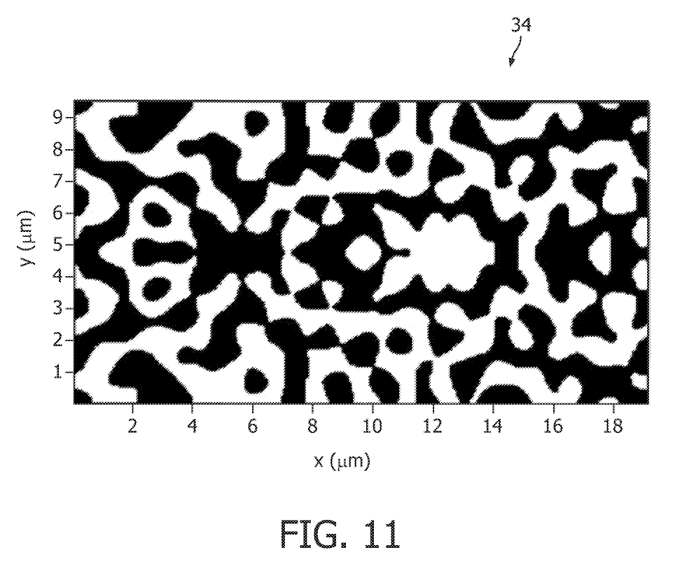

Referring now to FIG. 11, there is shown, by way of example, a unit cell 34 of a periodic binary phase structure for generating light spots situated in three different focal planes. The unit cell 34 is essentially a plane, two-dimensional transparent plate having two different height-values. Areas having a first height-value are indicated as black, and areas having a second height-value are indicated as white. The unit cell has an extension of 19 micrometers in the x-direction and of 9.5 micrometers in the y-direction. Note that the pattern satisfies periodic boundary conditions in x and y, that is, the pattern at the left edge (x=0) is identical to the pattern at the right edge (x=19), and the pattern at the bottom edge (y=0) is identical to the pattern at the top edge (y=9.5). The unit cell 34 is designed for a wavelength λ=655 nm, and the free working distance (i.e. the distance from the spot generator to the cover plate of the sample assembly) is 518 μm. When illuminated perpendicularly by light having the correct wavelength of 655 nm, a periodic assembly of identical unit cells 34 generates three light spots per unit cell 34, each light spot having a numerical aperture NA=0.65, and at distances of 142.5 μm, 145.0 μm, and 147.5 μm behind the interface air-cover plate (i.e. through the cover plate and several microns of sample layer). The lateral positions of these spots inside the unit-cell are (−pₓ/3, 0), (0, 0) and (+pₓ/3, 0), respectively.

All the embodiments described above enable to perform fast, simple and cheap the dimensional imaging thanks the efficient distribution of numerous light spots in different focal planes.

Although the present invention has been described above with reference to specific embodiment, it is not intended to be limited to the specific form set forth herein. Rather, the invention is limited only by the accompanying claims and, other embodiments than the specific above are equally possible within the scope of these appended claims.

In the claims, the term “comprises/comprising” does not exclude the presence of other elements or steps. Furthermore, although individually listed, a plurality of means, elements or method steps may be implemented by e.g. a single unit or processor. Additionally, although individual features may be included in different claims, these may possibly advantageously be combined, and the inclusion in different claims does not imply that a combination of features is not feasible and/or advantageous. In addition, singular references do not exclude a plurality. The terms “a”, “an”, etc do not preclude a plurality. Reference signs in the claims are provided merely as a clarifying example and shall not be construed as limiting the scope of the claims in any way.

1. A spot generator (10) having:
an entrance surface (12) for receiving an incident light beam (20), and
an exit surface (14) for transmitting the light beam,
the entrance surface defining an entrance side (16) and the exit surface defining an exit side (18), wherein the spot generator is designed to modulate the incident light beam to generate on the exit side a plurality of separate light spots, wherein the plurality of light spots comprises a first light spot (22) generated in a first focal plane (24) and a second light spot (26) generated in a second focal plane (28), the first focal plane and the second focal plane being essentially perpendicular to the mean propagation direction of the exit light beam, and wherein the first light spot (22) differs from every other light spot generated on the exit side by the spot generator in the projection of its position on a plane essentially perpendicular to the mean propagation direction of the exit light beam.

2. The spot generator (10) as claimed in claim 1, wherein the entrance surface (12) and the exit surface (14) are situated on opposite sides of the spot generator (10).

3. The spot generator (10) as claimed in claim 1, wherein the entrance surface (12) and the exit surface (14) are the same.

4. The spot generator (10) as claimed in claim 1, wherein the plurality of separate light spots comprises a first plurality of separate light spots situated in the first focal plane (24) and a second plurality of separate light spots situated in the second focal plane (28).

5. The spot generator (10) as claimed in claim 4, wherein the spot generator (10) comprises
a first section (30) for generating the first plurality of light spots, and
a second section (32) for generating the second plurality of light spots.

6. The spot generator (10) as claimed in claim 4, wherein the spot generator (10) comprises a plurality of identical unit cells (34) for generating both the first plurality of light spots and the second plurality of light spots.

7. The spot generator (10) as claimed in claim 1, wherein every light spot generated on the exit side (18) by the spot generator (10) differs from every other light spot generated on the exit side by the spot generator in the projection of its position on a plane essentially perpendicular to the mean propagation direction of the exit light beam (20).

8. The spot generator (10) as claimed in claim 1, wherein the light spots of the plurality of separate light spots have identical spectra.

9. The spot generator (10) as claimed in claim 1, wherein the spot generator (10) comprises a periodic binary phase structure.

10. A multi-spot scanning microscope (36) comprising:
a spot generator (10) as claimed in claim 1,
a sample assembly (38) for holding a sample to be illuminated via the spot generator,
imaging optics (40) arranged to collect light from the first and from the second focal planes (24, 28) of the spot generator, and
a pixelated photodetector (42) arranged to detect light collected by the imaging optics.

11. A method of generating an image of a microscopic sample, comprising the steps of:
placing a spot generator (10) in front of the sample;
directing a light beam (20) onto the spot generator to generate a plurality of separate light spots in the sample, the plurality of light spots comprising a first light spot (22) centred in a first focal plane (24) and a second light spot (26) centred in a second focal plane (28), the first focal plane (24) and the second focal plane (26) being essentially perpendicular to the mean propagation direction of the light beam leaving the spot generator, wherein the first light spot differs from every other light spot generated within the sample by the spot generator in the projection of its position on a plane essentially perpendicular to the mean propagation direction of the light beam leaving the spot generator;
detecting light from the first light spot (22) while simultaneously detecting light from the second light spot (26).

12. The method as claimed in claim 11, comprising the additional step of:
generating a three-dimensional image of the sample.

13. The method as claimed in claim 11, comprising the additional step of:
generating a phase contrast image of the sample.

14. The method as claimed in claim 11, comprising the additional step of:
electronic focussing.
